(19) United States
(12) Patent Application Publication
(10) Pub. No.: US 2025/0072189 A1
(43) Pub. Date: Feb. 27, 2025

(54) DISPLAY PANEL

(71) Applicants: K-Jet Laser Tek Inc., Hsin Chu (TW); Rayleigh Vision Limited, Kowloon (HK)

(72) Inventors: Hung Lung Chen, Hsin Chu (TW); Wen Ching Hung, Hsin Chu (TW); Jr-Hau HE, Hsinchu City (TW); Chun-wei TSAI, New Taipei City (TW); Zhi Ting Ye, Miaoli County (TW); Der-Hsien Lien, Taipei (TW); YUK TONG CHENG, Kowloon (HK)

(21) Appl. No.: 18/777,604

(22) Filed: Jul. 19, 2024

(30) Foreign Application Priority Data
Aug. 23, 2023 (CN) 202311067914.5

(51) Int. Cl. H01L 33/62; H01L 25/075

(52) U.S. Cl. CPC H01L 33/62; H01L 25/0753

(57) ABSTRACT

A display panel includes a substrate and a plurality of pixel structures disposed on the substrate. Each of the pixel structures includes a first light-emitting element, a second light-emitting element, and a third light-emitting element. The first light-emitting element is disposed on the substrate and configured to generate a first colored light. A light output surface of the first light-emitting element includes a combined region. The second light-emitting element is disposed on a part of the combined region and configured to generate a second colored light. The third light-emitting element is disposed on the other part of the combined region and configured to generate a third colored light.

### FIELD OF THE INVENTION

The present invention relates to a display panel.

### BACKGROUND OF THE INVENTION

A light-emitting diode display (LED display) is a type of display using light-emitting diodes as the light source. A micro light-emitting diode is a product where light-emitting diodes (LEDs) are made into thin films, miniaturized, and arrayed, with the size of the LEDs reduced to the micron level. The micro light-emitting diode display (LED display) manufactured using micro light-emitting diodes (micro LEDs) has many advantages such as high brightness, high resolution, high contrast, and energy saving.

However, when the size of light-emitting diodes is reduced to the micron level, the difficulty of manufacturing increases. Therefore, the structure of the light-emitting elements in the light-emitting diode display becomes relatively difficult to manufacture and maintain.

### SUMMARY OF THE INVENTION

The present invention provides a display panel, having the advantage of being easily produced and maintained.

To achieve the foregoing advantages, an embodiment of the present invention provides a display panel, including a substrate and a plurality of pixel structures. The pixel structures are disposed on the substrate, where each pixel structure includes a first light-emitting element, a second light-emitting element, and a third light-emitting element. The first light-emitting element is disposed on the substrate and configured to generate a first colored light, and a light output surface of the first light-emitting element includes a combined region. The second light-emitting element is disposed on a part of the combined region and configured to generate a second colored light. The third light-emitting element is disposed on the other part of the combined region and configured to generate a third colored light.

In an embodiment of the present invention, the first light-emitting element, the second light-emitting element, and the third light-emitting element each include a first electrode and a second electrode. The first electrode and the second electrode both face the substrate, and each pixel structure further includes a plurality of third electrical-connection members and a plurality of second electrical-connection members. The first electrode and the second electrode of the first light-emitting element are both electrically connected to the substrate. The first electrodes of the second light-emitting element and the third light-emitting element are electrically connected to the substrate via the third electrical-connection members, respectively. The second electrodes of the second light-emitting element and the third light-emitting element are electrically connected to the second electrode of the first light-emitting element via the second electrical-connection members, respectively.

In an embodiment of the present invention, the second light-emitting element and the third light-emitting element each include a first electrode and a second electrode. The first electrode and the second electrode of the first light-emitting element are respectively located on two opposite sides of the first light-emitting element. The first electrode of the first light-emitting element faces the substrate. The first electrodes and the second electrodes of the second light-emitting element and the third light-emitting element all face the substrate, and each pixel structure further includes a plurality of third electrical-connection members and a plurality of second electrical-connection members. The first electrode of the first light-emitting element is electrically connected to the substrate. The first electrodes of the second light-emitting element and the third light-emitting element are electrically connected to the substrate via the third electrical-connection members, respectively. The second electrodes of the second light-emitting element and the third light-emitting element are electrically connected to the second electrode of the first light-emitting element and the substrate via the second electrical-connection members, respectively.

In an embodiment of the present invention, the light output surface of the first light-emitting element further includes a non-combined region.

In an embodiment of the present invention, the combined region and the non-combined region are apart from each other.

In an embodiment of the present invention, the combined region includes two combined sub-regions apart from each other, and the second light-emitting element and the third light-emitting element are respectively disposed on the two combined sub-regions.

In an embodiment of the present invention, the non-combined region includes a plurality of non-combined sub-regions apart from each other.

In an embodiment of the present invention, the first light-emitting element includes a plurality of light-emitting members apart from each other, and the two combined sub-regions and the non-combined sub-regions are each a light output surface of the light-emitting member.

In an embodiment of the present invention, in the same pixel structure of the display panel, an area of the light output surface of the first light-emitting element is represented by A1, a totaled area of a light output surface of the second light-emitting element and a light output surface of the third light-emitting element is represented by A2, and A1 is greater than or equal to A2.

In an embodiment of the present invention, A1:A2 is 1:1, 2:1, or 3:2.

In an embodiment of the present invention, the first light-emitting element, the second light-emitting element, and the third light-emitting element are all micro light-emitting diodes.

In an embodiment of the present invention, the first colored light is a red light.

Through the foregoing description, in the display panel of the present invention, each pixel structure includes the first light-emitting element, the second light-emitting element, and the third light-emitting element that emit different colored lights, the second light-emitting element and the third light-emitting element are disposed on the light output surface of the first light-emitting element, showing a double-layer structure, and therefore the display panel is easy to manufacture and maintain.

Other objectives, features, and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a schematic diagram of a display panel according to an embodiment of the present invention;

FIG. 2 is a schematic diagram of a three-dimensional structure of a pixel structure according to an embodiment of the present invention;

FIGS. 3A to 3C are schematic diagrams of the combination of the sub-pixel structures in FIG. 2;

FIG. 4 is a schematic diagram of a side surface of the sub-pixel structure combined by the light-emitting elements in FIGS. 3A to 3C;

FIGS. 5A to 5C are schematic diagrams of the combination of the light-emitting elements according to another embodiment of the present invention;

FIG. 6 is a schematic diagram of a side surface of a pixel structure combined by the light-emitting elements in FIGS. 5A to 5C; and

FIGS. 7A to 7F are schematic diagrams of a pixel structure according to a plurality of practicable embodiments of the present invention.

### DETAILED DESCRIPTION OF PREFERRED EMBODIMENTS

Terms used in the description of the embodiments of the present invention, for example, orientation or position relation such as “above” and “below” are described according to the orientation or position relation shown in the drawings. The above terms are used for facilitating the description of the present invention rather than limiting the present invention, i.e., indicating or implying that the mentioned elements have to have specific orientations and to be configured in the specific orientations. In addition, terms such as “first” and “second” involved in the description or claims are merely used for naming the elements or distinguishing different embodiments or ranges rather than limiting the upper limit or lower limit of the quantity of the elements.

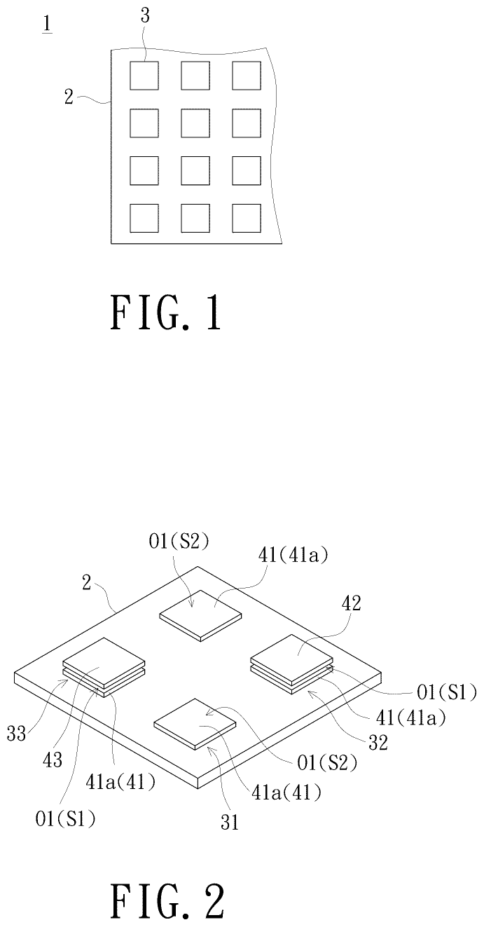

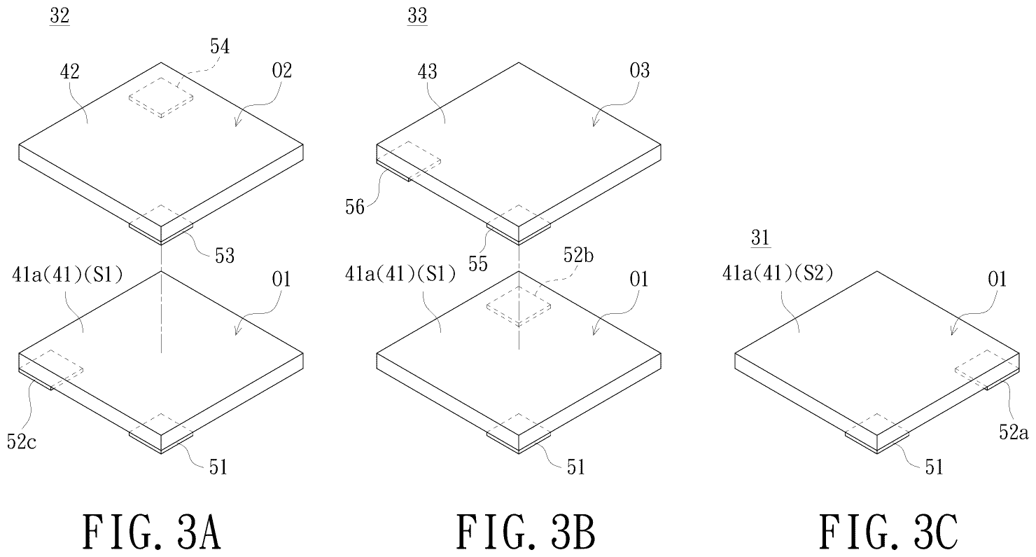

FIG. 1 is a schematic diagram of a display panel according to an embodiment of the present invention. FIG. 2 is a schematic diagram of a three-dimensional structure of a pixel structure according to an embodiment of the present invention. Referring to FIGS. 1 and 2, the display panel 1 provided by an embodiment of the present invention includes a substrate 2 and a plurality of pixel structures 3. The pixel structures 3 are disposed on the substrate 2. Each of the pixel structures 3 includes a first light-emitting element 41, a second light-emitting element 42, and a third light-emitting element 43. The first light-emitting element 41 is disposed on the substrate 2 and configured to generate a first colored light. The light output surface O1 of the first light-emitting element 41 includes a combined region S1. The second light-emitting element 42 is disposed on a part of the combined region S1 and configured to generate a second colored light. The third light-emitting element 43 is disposed on the other part of the combined region S1 and configured to generate a third colored light.

The substrate 2 in this embodiment is, for example, a complementary metal-oxide-semiconductor substrate (CMOS substrate), but not limited thereto. The first light-emitting element 41, the second light-emitting element 42, and the third light-emitting element 43 are all, for example, micro light-emitting diodes (μLEDs), but not limited thereto. The second light-emitting element 42 and the third light-emitting element 43 are, for example, transparent. Thus, when they are stacked perpendicularly, the colored light generated by the first light-emitting element 41 located below can penetrate through the second light-emitting element 42 and the third light-emitting element 43 located above and be emitted out. The first colored light is, for example, red light. The second colored light is, for example, green light. The third colored light is, for example, blue light.

In this embodiment, because the light output surface O1 of the first light-emitting element 41 has a larger area compared with the light output surface of other light-emitting elements, the type of the first light-emitting element 41 can be selected based on the requirement of the product. For example, in the embodiment where the first light-emitting element is a red micro light-emitting diode, because the red micro light-emitting diode has weaker light-emitting intensity compared with the light-emitting element with another colored light, and therefore the color control performance of each pixel structure in the unit can be controlled by increasing the area of the light output surface, but the type of the first light-emitting element 41 is not limited thereto.

As shown in FIG. 2, in this embodiment, the first light-emitting element 41 includes, for example, four light-emitting members 41a in the same size and shape, but is not limited thereto. In another embodiment, each light-emitting element 41 may include one or more light-emitting members 41a. Each light-emitting member 41a is, for example, a micro light-emitting diode. The second light-emitting element 42 and the third light-emitting element 43 each are, for example, a light-emitting diode. In another embodiment, the second light-emitting element 42 and the third light-emitting element 43 each may include a plurality of light-emitting members. In addition, each pixel structure 3 includes, for example, four sub-pixel structures. The four sub-pixel structures include two first sub-pixel structures 31, one second sub-pixel structure 32, and one third sub-pixel structure 33. Each first sub-pixel structure 31 is formed by, for example, one independent light-emitting member 41a. The second sub-pixel structure 32 is formed by stacking one light-emitting member 41a and one second light-emitting element 42. The third sub-pixel structure 33 is formed by stacking one light-emitting member 41a and one third light-emitting element 43. In addition, the light output surface O1 includes, for example, the light output surfaces of the light-emitting members 41a. The output surface O2 of the second light-emitting element 42 and the output surface O3 of the third light-emitting element 43 are both squares with the same area size and shape as the output surface of the light-emitting element 41a, but are not limited thereto.

In FIG. 2, the light output surfaces of the light-emitting members 41a forming the second sub-pixel structure 32 and the third sub-pixel structure 33 are set as the combined region S1, and the light output surface of the light-emitting member 41a forming the first sub-pixel structure 31 is set as the non-combined region S2. Because the first sub-pixel structure 31, the second sub-pixel structure 32, and the third sub-pixel structure 33 in this embodiment are apart from each other, the combined region S1 and the non-combined region S2 are apart from each other. In addition, the combined region S1 and the non-combined region S2 are respectively separated into, for example, two combined sub-regions (the two combined regions S1 shown in FIG. 2 each are a combined sub-region) apart from each other and two non-combined sub-regions (the two non-combined regions S2 shown in FIG. 2 each are a non-combined sub-region) apart from each other. The two combined sub-regions and the two non-combined sub-regions are all the light output surfaces of the light-emitting members 41a. The second light-emitting element 42 and the third light-emitting element 43 are each disposed in a respective combined sub-region.

In the embodiment of FIG. 2, the area (referred to as A1 hereafter) of the light output surface O1 of the first light-emitting element 41 in each pixel structure 3 is greater than the totaled area (referred to as A2 hereafter) of the light output surface O2 of the second light-emitting element 42 and the light output surface O3 of the third light-emitting element 43 in each pixel structure 3. In this embodiment, the ratio of A1 to A2 is, for example, 2:1, but the present invention is not limited thereto.

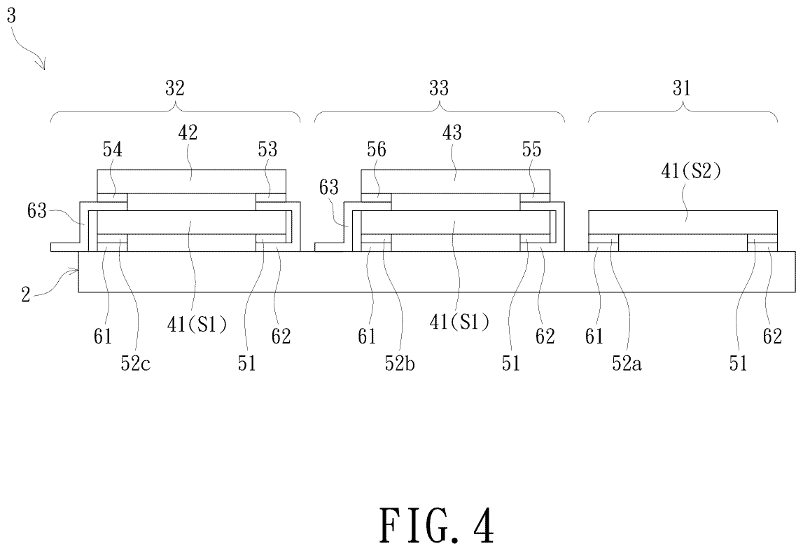

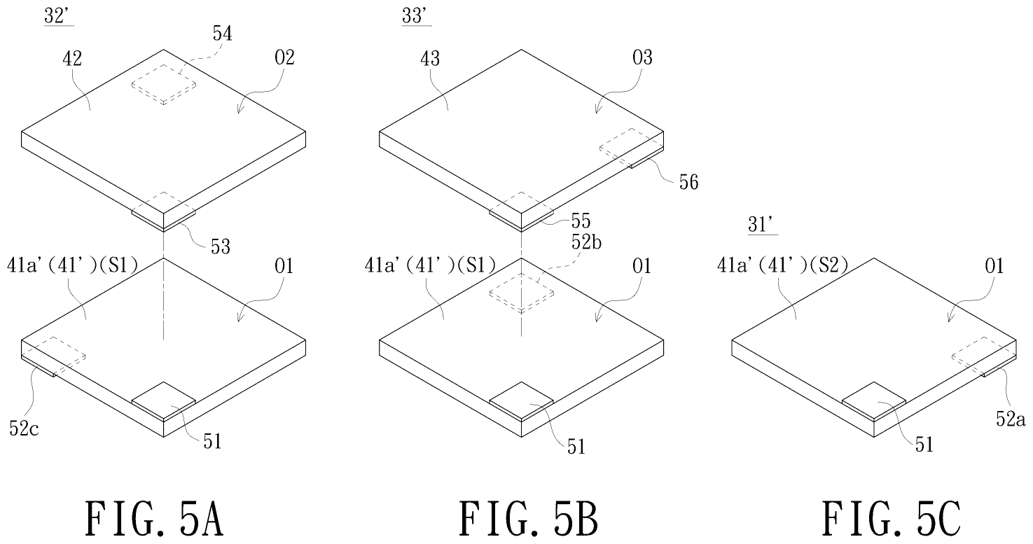

FIGS. 3A to 3C are schematic, exploded, three-dimensional diagrams of the respective sub-pixel structure in FIG. 2. FIG. 4 is a schematic cross-sectional diagram of the sub-pixel structure combined by the light-emitting elements in FIGS. 3A to 3C. Specifically, FIG. 3A is a schematic diagram of the second sub-pixel structure 32, FIG. 3B is a schematic diagram of the third sub-pixel structure 33, and FIG. 3C is a schematic diagram of the first sub-pixel structure 31. It should be noted that FIG. 4 is mainly used to illustrate the arrangement relationship of the sub-pixel structures in the perpendicular direction and does not correspond to the horizontal arrangement shown in FIGS. 2 and 3A to 3B.

As shown in FIGS. 3A and 4, in this embodiment, the second sub-pixel structure 32 includes a first light-emitting element 41 (i.e., the light-emitting member 41a) and a second light-emitting element 42 that are stacked on the substrate 2 in the perpendicular direction. The light-emitting member 41a of the first light-emitting element 41 includes, for example, a second electrode 51 facing the substrate 2 and a first electrode 52c. The second electrode 51 is, for example, an n-pole, and the first electrode 52c is, for example, a p-pole, but not limited thereto. The second light-emitting element 42 includes, for example, a second electrode 53 facing the substrate 2 and a first electrode 54. The second electrode 53 is, for example, an n-pole, and the first electrode 54 is, for example, a p-pole, but not limited thereto.

As shown in FIGS. 3B and 4, in this embodiment, the third sub-pixel structure 33 includes a light-emitting member 41a and a third light-emitting element 43 that are stacked on the substrate 2 in the perpendicular direction. The light-emitting member 41a includes, for example, a second electrode 51 facing the substrate 2 and a first electrode 52b. The second electrode 51 is, for example, an n-pole, and the first electrode 52b is, for example, a p-pole, but not limited thereto. The third light-emitting element 43 includes, for example, a second electrode 55 facing the substrate 2 and a first electrode 56. The second electrode 55 is, for example, an n-pole, and the first electrode 56 is, for example, a p-pole, but not limited thereto. In other words, the material types of the electrodes are interchangeable.

It can be known from FIGS. 3A and 3B that the relative relationship between the second electrode 53 and the first electrode 54 of the second light-emitting element 42 is different from the relative relationship between the second electrode 55 and the first electrode 56 of the third light-emitting element 43. In FIG. 3A, the second electrode 53 and the first electrode 54 of the second light-emitting element 42 are located in a diagonal direction of the back surface of the light output surface O2. In FIG. 3B, the first electrode 56 and the second electrode 55 of the third light-emitting element 43 are located on the same side of the back surface of the light output surface O1, but not limited thereto. It can be known from FIGS. 3A to 3B that the relative position between the second electrode 51 and the first electrode 52b on one light-emitting member 41a of the first light-emitting element 41 and the relative positions between the second electrode 51 and the first electrode 52c on another light-emitting member 41a of the first light-emitting element 41 can be changed based on requirements, and may further be different from the relative position described as follows between the first electrode 52a and the second electrode 51.

As shown in FIGS. 3A and 4, in the second sub-pixel structure 32, the first electrode 54 of the second light-emitting element 42 located above the first light-emitting element 41 is electrically connected to the substrate 2 via the third electrical-connection member 63, and the second electrode 53 is electrically connected to the substrate 2 via the second electrical-connection member 62. The position of the second electrode 51 of the light-emitting member 41a corresponds to, for example, the position of the second electrode 53 of the second light-emitting element 42 and is located under the second electrode 53. The first electrode 52c is in a different position. The first electrode 52c of the light-emitting member 41a is electrically connected to the substrate 2 via the first electrical-connection member 61, and the second electrode 51 is also electrically connected to the substrate 2 via the second electrical-connection member 62. That is, the second electrodes 51 and 53 are arranged as a common electrode.

It can be known from FIG. 4 that the second electrical-connection member 62 in this embodiment is specifically, for example, U-shaped, with one end connected to the second electrode 53 of the second light-emitting element 42 and the other end electrically connected to the second electrode 51 of the light-emitting member 41a and the substrate 2, and is located between the second electrode 51 of the light-emitting member 41a and the substrate 2.

It can be known from the above construction that the second electrode 51 of the light-emitting member 41a and the second electrode 53 of the second light-emitting element 42 in the second sub-pixel structure 32 are electrically connected to each other. However, the second electrode 51 and the second electrode 53 can be independently controlled via the conduction or not of the third electrical-connection member 63 and the first electrical-connection member 61.

Similarly, in FIGS. 3B and 4, the third sub-pixel structure 33 includes the light-emitting member 41a and the third light-emitting element 43 that are stacked on the substrate 2 in the perpendicular direction. Please refer to the design of the second sub-pixel structure 32 for the connection relationships and their shape design between the light-emitting member 41a, the first electrical-connection member 61, the second electrical-connection member 62, and the third electrical-connection member 63 in the third sub-pixel structure 33, and no redundant detail is to be given herein. As shown in FIGS. 3B and 4, the third light-emitting element 43 includes, for example, a first electrode 56 and a second electrode 55 facing the substrate 2. The second electrode 55 is, for example, an n-pole, and the first electrode 56 is, for example, a p-pole, but not limited thereto.

As shown in FIGS. 3B and 4, in the third sub-pixel structure 33, the first electrode 56 of the third light-emitting element 43 located above the first light-emitting element 41 is electrically connected to the substrate 2 via the third electrical-connection member 63, and the second electrode 55 is electrically connected to the substrate 2 via the second electrical-connection member 62. The position of the second electrode 51 of the light-emitting member 41a also corresponds to, for example, the position of the second electrode 55 of the second light-emitting element 42 and is located under the second electrode 55. And, the first electrode 52a is in a different position. In this embodiment, the second electrodes 51 and 55 are arranged as a common electrode.

It can be known from the above description that the light-emitting member 41a and the third light-emitting element 43 in the third sub-pixel structure 33 are stacked, but, similarly, they can be independently controlled, such as startup timing or brightness, via the conduction or not of the third electrical-connection member 63 and the first electrical-connection member 61.

In addition, the positions of the first electrode 52a, the first electrode 52b, the first electrode 52c, and the second electrode 51 of the light-emitting member 41a of the first light-emitting element 41, the first electrode 54 and the second electrode 53 of the second light-emitting element 42, and the first electrode 56 and the second electrode 55 of the third light-emitting element 43 can be changed based on the wiring requirements. For example, in another embodiment, the first electrode 52c and the second electrode 51 of the light-emitting member 41a in the second sub-pixel structure 32 may be located on a side of the light-emitting member 41a away from the substrate 2, and electrical connection is avoided between the electrodes of the second light-emitting element 42 and the electrodes of the light-emitting member 41a through, for example, misplacement, to independently control the light-emitting member 41a and the second light-emitting element 42. Alternatively, in some embodiments, the first electrode 54 and the second electrode 53 of the second light-emitting element 42 may face the side away from the substrate 2, and the third electrical-connection member 63 and the second electrical-connection member 62 are correspondingly changed.

Through the above structure, the first sub-pixel structure 31, the second sub-pixel structure 32, and the third sub-pixel structure 33 in the embodiment shown in FIG. 2 serve as the light-emitting members 41a of the first light-emitting element 41 and are all in contact with the substrate 2 and at the same height (with respect to the substrate 2). Thus, during manufacturing, all the first sub-pixel structure 31, second sub-pixel structure 32, and third sub-pixel structure 33 serving as the light-emitting members 41a of the first light-emitting elements 41 can be arranged in the same process, and the second light-emitting elements 42 and the third light-emitting elements 43 are assembled in a second process and a third process that are different. In addition, because the pixel structure 3 is divided into a plurality of sub-pixel structures, it can be easily replaced by removing a single sub-pixel structure when an element in one of the sub-pixel structures is damaged. Therefore, the pixel structure of the present invention has the advantages of simple manufacturing and maintenance.

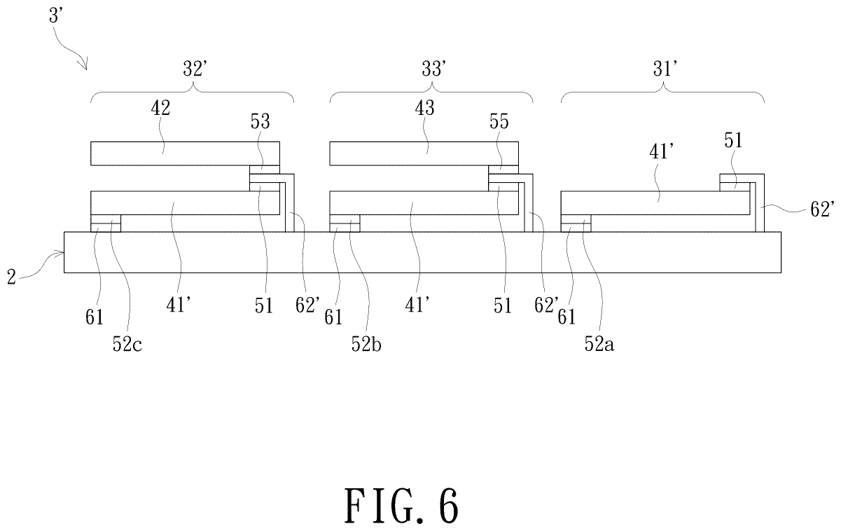

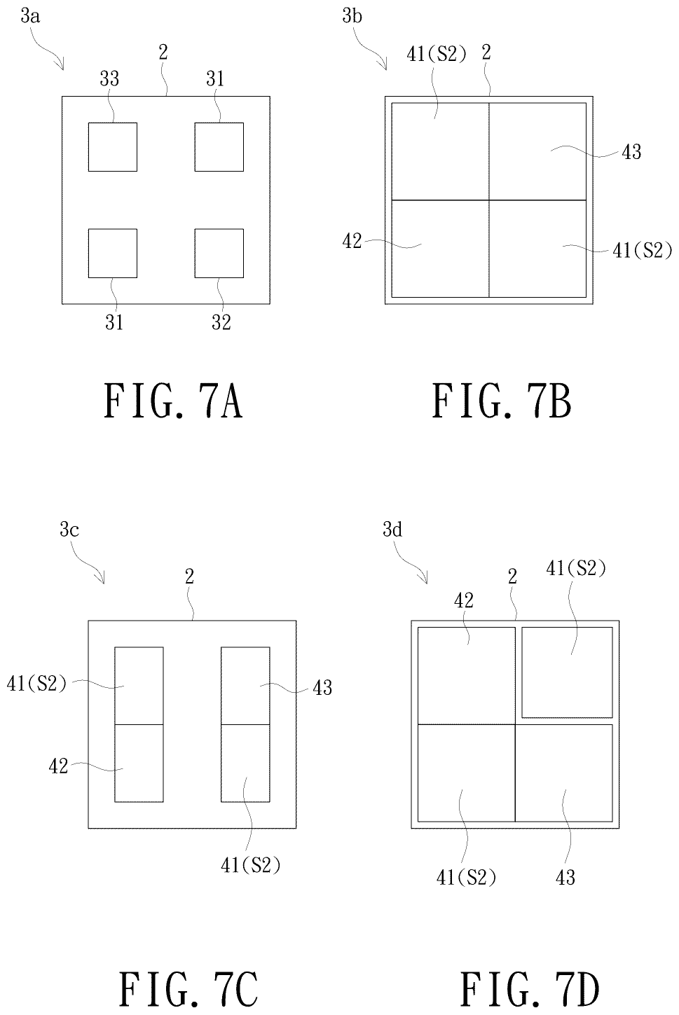

FIGS. 5A to 5C are schematic diagrams of light-emitting elements being combined according to another embodiment of the present invention. FIG. 6 is a schematic diagram of a side surface of a pixel structure combined by the light-emitting elements in FIGS. 5A to 5C. Please refer to FIG. 4 for the manner of electrically connecting the first electrode 54 and the first electrode 56 in FIG. 6 to the substrate 2 via the third electrical-connection member 63, and such manner is not illustrated but only described in text.

In the embodiment shown in FIGS. 5A to 6, a pixel structure 3′ (not shown in the figure) includes, for example, a first sub-pixel structure 31′, a second sub-pixel structure 32′, and a third sub-pixel structure 33′. In this embodiment, the first light-emitting element 41′ is divided into a plurality of light-emitting members 41a′ spaced apart from each other. The first sub-pixel structure 31′ is formed by a single light-emitting member 41a′. The second sub-pixel structure 32′ and the third sub-pixel structure 33′ are respectively formed by one light-emitting member 41a′ with a second light-emitting element 42 and one light-emitting member 41a′ with the third light-emitting element 43. The first electrode (e.g., first electrodes 52a, 52b, and 52c) and the second electrode (e.g., the second electrode 51) of the light-emitting member 41a′ are respectively located on two opposite sides of the light-emitting member 41a′. For example, the first electrode 52a, the first electrode 52b, and the first electrode 52c of the first light-emitting element 41′ face the substrate 2, and the second electrode 51 faces the side away from the substrate 2. For example, the first electrode 54 (not shown in the figure) and the second electrode 53 of the second light-emitting element 42 and the first electrode 56 (not shown in the figure) and the second electrode 55 of the third light-emitting element 43 all face the substrate 2. The second electrode 51 of the light-emitting member 41a′ is opposite the second electrode 53 of the second light-emitting element 42 or the second electrode 55 of the third light-emitting element 43, and all of them are, for example, n-poles.

It can be known from FIGS. 5A and 5B that the relative relationship between the first electrode 54 and the second electrode 53 of the second light-emitting element 42 is different from the relative relationship between the first electrode 56 and the second electrode 55 of the third light-emitting element 43. In FIG. 5A, the first electrode 54 and the second electrode 53 of the second light-emitting element 42 are located in a diagonal direction of the back surface of the light output surface of the light-emitting member 41a′. In FIG. 5B, the first electrode 56 and the second electrode 55 of the third light-emitting element 43 are located on the same side of the back surface of the light output surface of the light-emitting member 41a′, but not limited thereto.

During assembly, same as shown in the embodiment of FIG. 4, the first electrode 54 of the second light-emitting element 42 located above the second sub-pixel structure 32′ is electrically connected to the substrate 2 via the third electrical-connection member 63. Referring to FIG. 6, the second electrode 53 is electrically connected to the substrate 2 via the second electrical-connection member 62′. The second electrode 51 of the light-emitting member 41a′ is connected to the substrate 2 via the second electrical-connection member 62′. The first electrode 52c is connected to the substrate 2 via the first electrical-connection member 61. The second electrode 51 of the light-emitting member 41a′ in this embodiment corresponds in position to the second electrode 53 of the second light-emitting element 42 and is located below the second electrode 51. Thus, the second electrode 51 and the second electrode 53 are connected to the upper and lower sides of one end of the second electrical-connection member 62′. In more detail, one end of the second electrical-connection member 62′ in this embodiment is electrically connected to the substrate 2, and the upper and lower sides of the other end are respectively connected to the second electrode 51 and the second electrode 53.

Through the above structure, the light-emitting member 41a′ and the second light-emitting element 42 of the second sub-pixel structure 32′ are stacked; however, the light-emitting member 41a′ and the second light-emitting element 42 can be independently controlled (e.g., the start time and brightness) via the conduction or not of the third electrical-connection member 63 (not shown in the figure) and the first electrical-connection member 61.

Regarding the detailed design of the third sub-pixel structure 33′, as shown in FIG. 5B, except for the relative relationship between the positions of the first electrode 56 and the second electrode 55 of the third light-emitting element 43 is different from the relative positional relationship between the first electrode 54 and the second electrode 53 of the element 42′, the rest of the design can refer to the aforementioned design of the second sub-pixel structure 32′, and no redundant detail is to be given herein.

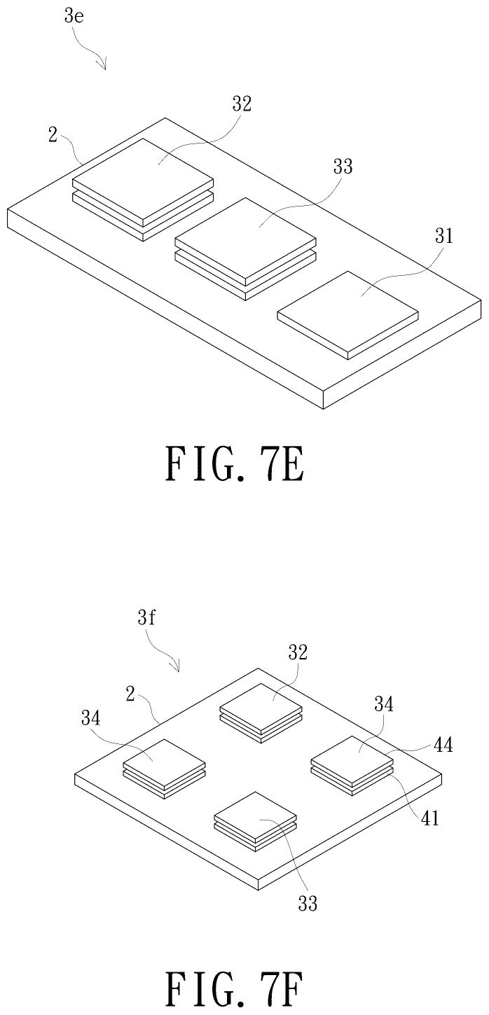

FIGS. 7A to 7F are schematic structural diagrams of a pixel structure according to other embodiments of the present invention. The pixel structure 3a in FIG. 7A has the same structure as the pixel structure 3 in FIG. 2, and no redundant detail is to be given herein.

In the pixel structure 3b of the embodiment of FIG. 7B, the first light-emitting element 41 is, for example, a single light-emitting member, and the sum of the area of the light output surface O2 (not shown in FIG. 7B) of the second light-emitting element 42 and the area of the light output surface O3 (not shown in FIG. 7B) of the third light-emitting element 43 is smaller than the area of the light output surface O1 (not shown in FIG. 7B) of the first light-emitting element 41. During assembly, the light output surface O1 (not shown in FIG. 7B) of the first light-emitting element 41 is directly divided, based on the position, into a combined region S1 (being covered and not shown in FIG. 7B) and a non-combined region S2, and the second light-emitting element 42 and the third light-emitting element 43 are assembled on the combined region S1.

In the pixel structure 3c of the embodiment of FIG. 7C, the first light-emitting element 41 is divided, for example, into two light-emitting members apart from each other and rectangular. The light output surface O1 (not shown in FIG. 7C) of each light-emitting member is also divided into a combined region S1 (not shown in FIG. 7C) and a non-combined region S2. The area of the light output surface O2 (not shown in FIG. 7C) of the second light-emitting element 42 and the area of the light output surface O2 (not shown in FIG. 7C) of the third light-emitting element 43 are smaller than the area of the light output surface O1 of the first light-emitting element 41. In other words, the pixel structure 3c is divided into two different sub-pixel structures, where elements connected on the different first light-emitting element 41 are different.

In the pixel structure 3d of the embodiment of FIG. 7D, the first light-emitting element 41 is divided into, for example, two light-emitting members apart from each other. One of the light-emitting members is, for example, square, and the other one is, for example, polygonal. The light output surface O1 (not shown in FIG. 7D) of the polygonal light-emitting member is divided into a combined region S1 (not shown in FIG. 7D) and a non-combined region S2. The area of the light output surface O2 (not shown in FIG. 7D) of the second light-emitting element 42 and the area of the light output surface O3 (not shown in FIG. 7C) of the third light-emitting element 43 are smaller than the area of the light output surface O1 of the first light-emitting element 41. However, in the same pixel structure 3d, a ratio of the area A1 of the light output surface O1 of the first light-emitting element 41 to the totaled area A2 of the light output surfaces of the second light-emitting element 42 and the third light-emitting element 43 is still 2:1. In other words, the pixel structure 3c is divided into two different sub-pixel structures. One of the sub-pixel structures is provided with another light-emitting element, and the other one does not have another light-emitting element.

Referring to FIG. 7E, the pixel structure 3e of the embodiment of FIG. 7E is divided into, for example, a first sub-pixel structure 31, a second sub-pixel structure 32, and a third sub-pixel structure 33. Please refer to the embodiment of FIG. 2 or FIG. 6 for the detailed construction of the first sub-pixel structure 31, the second sub-pixel structure 32, and the third sub-pixel structure 33, and no redundant detail is to be given herein. It can be known from FIG. 7E that in the pixel structure 3e of this embodiment, the ratio of the area A1 of the light output surface O1 (not shown in FIG. 7E) of the first light-emitting element 41 to the totaled area A2 of the light output surface O2 of the second light-emitting element 42 and the light output surface O3 (not shown in FIG. 7E) of the third light-emitting element 43 is changed to 3:2.

Referring to FIG. 7F, the pixel structure 3f of the embodiment of FIG. 7F is divided into, for example, a second sub-pixel structure 32, a third sub-pixel structure 33, and two fourth sub-pixel structures 34. Please refer to the foregoing description for the construction of the second sub-pixel structure 32 and the third sub-pixel structure 33, and no redundant detail is to be given herein.

In this embodiment, the fourth sub-pixel structure 343 includes the light-emitting members divided from the first light-emitting element 41 and the fourth light-emitting element 44 on the light-emitting member. The type of the fourth light-emitting element 44 is not limited and may be similar to one of the first light-emitting element 41, the second light-emitting element 42, and the third light-emitting element 43, or may be a micro light-emitting diode emitting a fourth colored light different from the first colored light, the second colored light, and the third colored light.

It can be known from FIG. 7F that in some embodiments, the ratio of A1 to A2 can be changed to 1:1 when the type of the fourth light-emitting element 44 is the same as the type of the second light-emitting element 42 or the third light-emitting element 43.

It can be known from the foregoing description that in the display panel of the present invention, each pixel structure includes a first light-emitting element, a second light-emitting element, and a third light-emitting element that emit different colored lights. The second light-emitting element and the third light-emitting element are disposed on the light output surface of the first light-emitting element, thereby showing a double-layer structure, and therefore the display panel is easy to manufacture and maintain.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A display panel, comprising:
a substrate; and
a plurality of pixel structures, disposed on the substrate, wherein each of the pixel structures comprises a first light-emitting element, a second light-emitting element, and a third light-emitting element; wherein
the first light-emitting element is disposed on the substrate and configured to generate a first colored light, and a light output surface of the first light-emitting element comprises a combined region;
the second light-emitting element is disposed on a part of the combined region and configured to generate a second colored light; and
the third light-emitting element is disposed on the other part of the combined region and configured to generate a third colored light.

2. The display panel according to claim 1, wherein the first light-emitting element, the second light-emitting element, and the third light-emitting element each comprise a first electrode and a second electrode, the first electrode and the second electrode both face the substrate, and each of the pixel structures further comprises a plurality of first electrical-connection members and a plurality of second electrical-connection members, wherein:
the first electrode and the second electrode of the first light-emitting element are electrically connected to the substrate;
the first electrodes of the second light-emitting element and the third light-emitting element are electrically connected to the substrate via the first electrical-connection members, respectively; and
the second electrodes of the second light-emitting element and the third light-emitting element are electrically connected to the second electrode of the first light-emitting element via the second electrical-connection members, respectively.

3. The display panel according to claim 1, wherein the second light-emitting element and the third light-emitting element each comprise a first electrode and a second electrode, the first electrode and the second electrode of the first light-emitting element are respectively located on two opposite sides of the first light-emitting element, the first electrode of the first light-emitting element faces the substrate, the first electrodes and the second electrodes of the second light-emitting element and the third light-emitting element all face the substrate, and each of the pixel structures further comprises a plurality of first electrical-connection members and a plurality of second electrical-connection members, wherein
the first electrode of the first light-emitting element is electrically connected to the substrate;
the first electrodes of the second light-emitting element and the third light-emitting element are electrically connected to the substrate via the first electrical-connection members, respectively; and
the second electrodes of the second light-emitting element and the third light-emitting element are electrically connected to the second electrode of the first light-emitting element and the substrate via the second electrical-connection members, respectively.

4. The display panel according to claim 1, wherein the light output surface of the first light-emitting element further comprises a non-combined region.

5. The display panel according to claim 4, wherein the combined region and the non-combined region are apart from each other.

6. The display panel according to claim 5, wherein the combined region comprises two combined sub-regions apart from each other, and the second light-emitting element and the third light-emitting element are respectively disposed on the two combined sub-regions.

7. The display panel according to claim 6, wherein the non-combined region comprises a plurality of non-combined sub-regions apart from each other.

8. The display panel according to claim 7, wherein the first light-emitting element comprises a plurality of light-emitting members apart from each other, and the two combined sub-regions and the non-combined sub-regions are each a light output surface of the light-emitting member.

9. The display panel according to claim 1, wherein in the same pixel structure, an area of the light output surface of the first light-emitting element is represented by A1, a sum of an area of a light output surface of the second light-emitting element and an area of a light output surface of the third light-emitting element is represented by A2, and A1 is greater than or equal to A2.

10. The display panel according to claim 9, wherein A1:A2 is 1:1, 2:1, or 3:2.

11. The display panel according to claim 1, wherein the first light-emitting element, the second light-emitting element, and the third light-emitting element are all micro light-emitting diodes.

12. The display panel according to claim 1, wherein the first colored light is a red light.
